(19) United States
(12) Patent Application Publication
(10) Pub. No.: US 2025/0040093 A1
(43) Pub. Date: Jan. 30, 2025

(54) IMMERSION COOLING SYSTEM AND TANK STRUCTURE THEREOF

(71) Applicant: KENMEC MECHANICAL ENGINEERING CO., LTD., Taipei City (TW)

(72) Inventors: Kuei-Yuan HUANG, Taipei City (TW); Yu-Long LU, Taipei City (TW)

(21) Appl. No.: 18/784,953

(22) Filed: Jul. 26, 2024

Related U.S. Application Data
(60) Provisional application No. 63/516,143, filed on Jul. 28, 2023.

(30) Foreign Application Priority Data
Nov. 24, 2023 (TW) 112145656

(51) Int. Cl. H05K 7/20

(52) U.S. Cl. CPC H05K 7/20327; H05K 7/203; H05K 7/20809

(57) ABSTRACT

The disclosure relates to an immersion cooling system and a tank structure thereof. The tank structure comprises a tank and a vapor chamber. The tank comprises a tank body, a door panel type condenser and a baffle. The door panel type condenser disposes on the top plane of the tank body and seals the tank body, and cool the electric vapor flowing to the top plane. One end of the baffle disposes on the top plane, and the other end of the baffle faces the liquid surface of the coolant in the tank body. The baffle divides a vapor space into a first vapor space and a second vapor space away from the door panel type condenser. The vapor chamber is connected to the tank body and used to cool the electric vapor flowing to the vapor chamber through the second vapor space.

### CROSS-REFERENCES

This application claims the priority benefit of U.S. provisional patent application No. 63/516,143, filed Jul. 28, 2023 and Taiwan Patent Application Serial Number 112145656, filed on Nov. 24, 2023, the full disclosure of which is incorporated herein by reference.

### TECHNICAL FIELD

The application relates to a cooling system, and particularly to an immersion cooling system and a tank structure thereof.

### DESCRIPTION OF RELATED ART

Immersion cooling is one of the technologies in liquid cooling, which involves submerging heat-generating devices in a non-conductive dielectric fluid. The heat generated by the heat-generating devices is rapidly dissipated through direct contact of the dielectric fluid, and thereby the head-generating device is effectively operated without overheating.

Immersion cooling technology is further categorized into single-phase immersion liquid cooling and two-phase immersion liquid cooling. The difference between the two liquid cooling technologies lies in that the dielectric fluid used in single-phase immersion liquid cooling has no phase change and maintains liquid, while the dielectric fluid used in two-phase immersion liquid cooling alternates between liquid and gas states as the temperature varies.

Since two-phase immersion liquid cooling technology involves the circulation and cooling through the conversion of the dielectric fluid between liquid and gas states, the condensing rate of the dielectric fluid from gas to liquid significantly impacts the overall cooling efficiency of the system. Meanwhile, the dielectric fluid gas may escape due to maintenance or equipment structure issues. Consequently, the cooling system's heat dissipation capacity is diminished, while the replenishment of the dielectric fluid is required more frequently, leading to increased overall costs.

Therefore, how to enhance the condensation efficiency of immersion cooling so as to reduce the system maintenance costs, is one of the pressing technical problems to be addressed in the field.

### SUMMARY OF THE INVENTION

The features of the exemplary embodiments believed to be novel and the elements and/or the steps characteristic of the exemplary embodiments are set forth with particularity in the appended claims. The Figures are for illustration purposes only and are not drawn to scale. The exemplary embodiments, both as to organization and method of operation, may best be understood by reference to the detailed description which follows taken in conjunction with the accompanying drawings in which:

To address the aforementioned technical problems, the application proposes an immersion cooling system and a tank structure thereof, which can improve the condensation efficiency of the dielectric fluid from gas to liquid, and effectively reduce the gas escape rate, thereby achieving technical effects such as enhanced cooling efficiency of the immersion cooling system, and reduced system maintenance costs.

To achieve the objective as described above, an embodiment of a tank structure for an immersion cooling system is proposed, comprising at least one tank and a vapor chamber. The at least one tank comprises a tank body, a door panel type condensing device, and a baffle. The tank body has a liquid space and a vapor space, wherein the liquid space is arranged to house a heater device and a coolant, the vapor space is arranged to accommodate electric vapor generated from the coolant, and the vapor space is positioned above the liquid space and adjacent to a top plane of the tank body. The door panel type condensing device is arranged at the top plane of the tank body, adaptable for sealing the tank body and cooling the electric vapor flowing through the top plane of the tank body. The baffle comprises one end positioned at the top plane of the tank body, and another end directed towards liquid surfaces of the coolant, segmenting the vapor space into a first vapor space near the door panel type condensing device and a second vapor space distal to the door panel type condensing device. The vapor chamber is connected to the tank body, adaptable for cooling the electric vapor flowing to the vapor chamber through the second vapor space.

To attend to the aforementioned objectives, another embodiment of the invention proposes an immersion cooling system, comprising at least one tank characterized with the tank structure as described, and a coolant distribution device. The coolant distribution device comprises a liquid-gas storage tank connected to the at least one tank through piping, adaptable for receiving electric vapor from the vapor chamber, and transmitting the coolant to the tank structure of the at least one tank after the coolant is condensed.

Building on the aforementioned details, the embodiment of the tank structure in the application features a baffle that divides the vapor space into a first and a second vapor space. The electric vapor may be quickly directed to the corresponding first and second vapor spaces through the baffle. Furthermore, the tank structure cools the electric vapor using both the door panel type condensing device and the vapor chamber, significantly enhancing the condensation efficiency of the electric vapor. Meanwhile, the tank structure in the embodiment includes a door panel type condensing device, allowing the electric vapor circulating to the top plane of the tank structure to be cooled down to a liquid state, preventing the electric vapor from escaping the cooling system through the door panel structure, such that the gas escape rate is significantly reduced. Therefore, the embodiments of the immersion cooling system and its tank structure are advantageous for enhanced cooling efficiency and reduced system maintenance costs.

### BRIEF DESCRIPTION OF DRAWINGS

FIG. 1 shows a schematic diagram of a tank structure according to an embodiment of the application.

FIG. 2 shows another schematic diagram of the tank structure according to an embodiment of the application.

FIG. 3 shows a perspective schematic diagram of a door panel type condensing device according to an embodiment of the application.

FIG. 4 shows a side view schematic diagram of a door panel type condensing device according to an embodiment of the application.

FIG. 5 shows another side view schematic diagram of a door panel type condensing device according to an embodiment of the application.

FIG. 6 shows a schematic diagram of a condensing device according to a first embodiment of the application.

FIG. 7 shows a schematic diagram of a condensing device according to a second embodiment of the application.

FIG. 8 shows a schematic diagram of a condensing device according to a third embodiment of the application.

FIG. 9 shows a schematic diagram of a condensing device according to a fourth embodiment of the application.

FIG. 10 shows a schematic diagram of a condensing device according to a fifth embodiment of the application.

FIG. 11 shows a schematic diagram of another embodiment of a door panel type condensing device according to the application.

FIG. 12 shows a side view schematic diagram of another embodiment of a door panel type condensing device according to the application.

FIG. 13 shows a schematic diagram of an immersion cooling system according to an embodiment of the application.

FIG. 14 shows another schematic diagram of the immersion cooling system according to an embodiment of the application.

### DESCRIPTION OF THE INVENTION

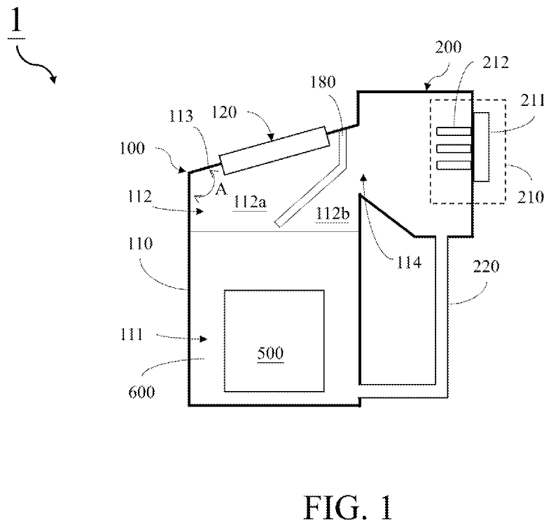

Refer to FIG. 1, a schematic diagram illustrates an embodiment of a tank structure of the instant application. This tank structure 1 includes at least one tank 100 and a vapor chamber 200, with the at least one tank 100 connected to the vapor chamber 200. The at least one tank 100 comprises a tank body 110, a door panel type condensing device 120, and a baffle 180.

The tank body 110 defines a liquid space 111, a vapor space 112, and a top plane 113. The top plane 113 is positioned on a side away from the liquid space 111, and the vapor space 112 is located between the liquid space 111 and the top plane 113. The liquid space 111 accommodates a heater device 500 and a coolant 600, creating the vapor space 112 above the liquid space 111 and near the top plane 113 of the tank body 110. One end of the top plane 113 is connected to the sidewall of the tank body 110, forming an angle A with the sidewall of the tank body 110, that is, the top plane 113 is configured at an inclined position relative to the tank body 110. In the embodiment, the angle A is greater than 90 degrees and less than 180 degrees. In this way, the heater device 500 placed in the tank body 110 is allowed to conduct heat through the surrounding coolant 600, wherein the coolant 600 is heated up into electric vapor that flows upwards into the vapor space 112.

In one embodiment, the heater device 500, for example, may be a server host device. Note that the actual implementation thereof is not limited to this embodiment.

The door panel type condensing device 120 is installed at the top plane 113 of the tank body 110 and is rotationally connected with the top plane 113, serving to seal the opening of the top plane 113 and cool the electric vapor circulating to the top plane 113 of the tank body 110. In one embodiment, the door panel type condensing device 120 is rotationally connected with the top plane 113 through a rotating door hinge assembly. In another embodiment, the door panel type condensing device 120 can directly cover the opening of the top plane 113. Note that the actual implementation thereof is not limited to this embodiment.

The baffle 180 has one end positioned at the top plane 113 of the tank body 110, and the other end elongated to proximate the liquid surface of the coolant 600. The baffle 180 divides the vapor space 112 into a first vapor space 112a being adjacent to the door panel type condensing device 120, and a second vapor space 112b being distal from the door panel type condensing device 120. In this embodiment, the baffle 180 is made of non-heat-conducting material, functioning as a non-heat-conducting baffle. Thus, the electric vapor is allowed to flow towards the first vapor space 112a and the second vapor space 112b through the baffle 180, and the circulation efficiency of electric vapor is enhanced.

In one embodiment, the baffle 180 is arranged to not cover the heater device 500. In this way, the installation or removal of the heater device 500 is facilitated, which also enhances the convenience of setting up the heater device 500.

In one embodiment, the baffle 180 may be made from flexible materials. This allows the baffle 180 to be bent or folded as required, which facilitates the installation or removal of the heater device 500, and also enhances the convenience of setting up the heater device 500.

In one embodiment, the baffle 180 features a foldable structure that may be folded to reduce the space occupation. For example, the baffle 180 may be but not limited to be implemented by two panels connected by a rotatable hinge structure. This design enables the baffle 180 to be bent or folded as required, which facilitates the installation or removal of the heater device 500, and also enhances the convenience of setting up the heater device 500.

In one embodiment, the baffle 180 may be positioned on the inner side of the door panel type condensing device 120. This allows the baffle 180 to be moved out of the tank body 110 as the door panel type condensing device 120 is moved or removed, such that the installation or removal of the heater device 500 is facilitated, and the heater device 500 may be set up more conveniently.

Furthermore, the tank body 110 has one side adjacent to the vapor chamber 200 equipped with an air vent 114. The vapor chamber 200 is in contact connection with the tank body 110 and is air flow connected to the second vapor space 112b through the air vent 114.

The vapor chamber 200 comprises a condenser unit 210 and a reflux pipeline 220. The condenser unit 210 comprises a condenser 211 and at least one condensing tube 212. The condenser 211 is positioned on the outer wall of the vapor chamber 200. The at least one condensing tube 212 is arranged within the vapor chamber 200 and passes between the inner and outer walls of the vapor chamber 200. The at least one condensing tube 212, located near the outer wall, is in contact connection with the condenser 211. The reflux pipeline 220 is connected to the tank body 110 through piping, allowing the coolant 600 in the vapor chamber 200 to flow back to the tank body 110 through the reflux pipeline 220 when the coolant 600 is condensed.

Therefore, when the coolant 600 is heated up and transformed into electric vapor by the heater device 500, the rising electric vapor is guided by the baffle 180 towards either the first vapor space 112a or the second vapor space 112b, such that the flow efficiency of the electric vapor is effectively enhanced. Since the baffle 180 is made from non-heat-conducting materials, the condensed coolant 600 is not vaporizable by the temperature of the baffle 180, thereby the condensation efficiency of the electric vapor is improved. The electric vapor flowing towards the first vapor space 112a is cooled by the door panel type condensing device 120 to be condensed into the coolant 600 of liquid state, such that the electric vapor is prevented from escaping through the opening, so as to reduce the gas escape rate. The electric vapor flowing towards the second vapor space 112b is cooled by the vapor chamber 200 to be condensed into the coolant 600 of liquid state, which thereafter flows back to the tank body 110 through the reflux pipeline 220. This process ensures that the cooled coolant 600 is not affected by the temperature of the electric vapor in the vapor chamber 200, thereby enhancing the condensation efficiency of the electric vapor. Thus, the tank structure embodiment of this application improves the cooling efficiency of the immersion cooling system while reducing the system maintenance costs.

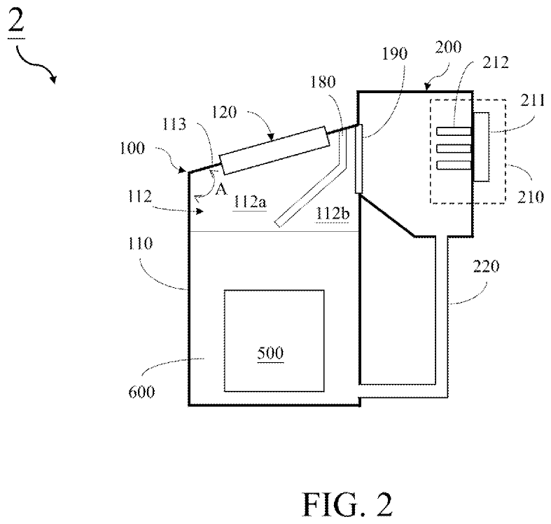

Next refer to FIG. 2, which illustrates a schematic diagram of a tank structure according to another embodiment of the application. The difference between the embodiments of the tank structure 2 and the tank structure 1 is that, the at least one tank 100 of tank structure 2 further comprises a chamber sealing device 190. The chamber scaling device 190 is connected to the tank body 110, positioned at the air vent 114, and located between the second vapor space 112b and the vapor chamber 200. The chamber sealing device 190 is used to selectively establish or block air flow connection between the second vapor space 112b and the vapor chamber 200. In one embodiment, the chamber scaling device 190 is a movable structure, allowing for the establishment or interruption of air flow connection between the second vapor space 112b and the vapor chamber 200 by opening or closing the movable structure. In this embodiment, the vapor chamber 200 may be connected to multiple tanks 100 simultaneously. The movable structure may be implemented with movable panels, connecting rods, slats, and etc., but the actual implementations in the application are not limited to the aforementioned embodiments. When a heater device 500 in one of the multiple tanks 100 requires maintenance or replacement, the air flow connection between the second vapor space 112b of each tank 100 and the vapor chamber 200 may be interrupted by closing the chamber sealing devices 190 of the other tanks 100, so as to prevent the electric vapor from escaping the tanks 100 during maintenance. Thus, the rate of gas escape is effectively reduced.

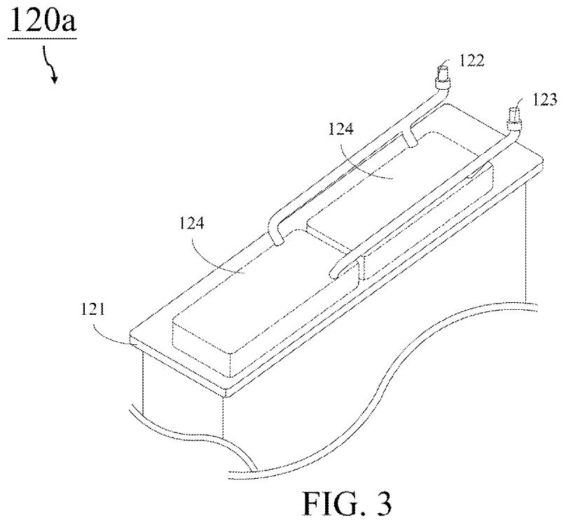

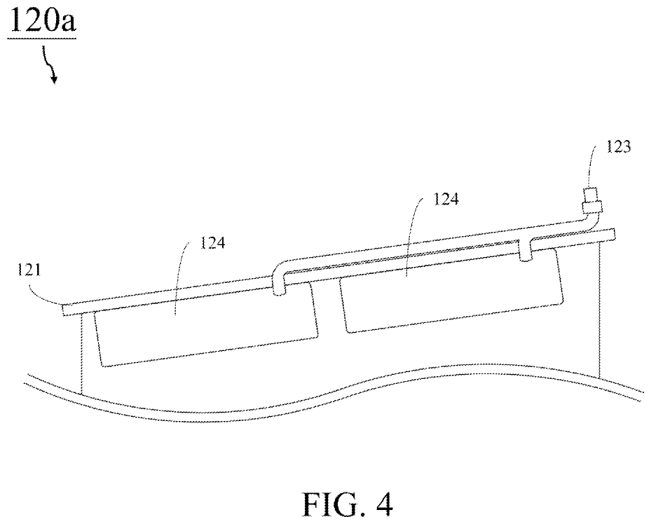

Refer to FIGS. 3 and 4. FIG. 3 is a perspective schematic diagram of a door panel type condensing device according to an embodiment of this application, and FIG. 4 illustrates a side view schematic diagram of the door panel type condensing device. The door panel type condensing device 120a includes a door panel 121, an inlet 122, a reflux port 123, and at least one condensing device 124. The door panel 121 has an inner side facing the vapor space 112 and an outer side opposite to the inner side. The door panel 121 is adapted to tightly couple with the top plane 113 to seal the top plane 113. The condensing device 124 is placed on the inner side of the door panel 121, connected to the inlet 122 and the reflux port 123 through piping. In the embodiment, the condensing device 124 is connected to the inlet 122 and the reflux port 123 through pipes on the outer side of the door panel 121. In this embodiment, the inlet 122 and the reflux port 123 may be connected to pipes of a heat exchange device through quick-disconnect fittings or hoses. Thus, the door panel type condensing device 120a is moveable without being restricted by the diverse pipes, and the heater device 500 may be set up more conveniently.

In this embodiment, the number of the condensing devices 124 may be one or plural, and the actual implementation is not limited to the quantity mentioned in this embodiment.

In one embodiment, the number of inlets 122 and reflux ports 123 may be plural. For example, each condensing device 124 may be connected to an exclusive set of inlet 122 and reflux port 123 through piping, wherein the exclusive set of inlets 122 and reflux ports 123 is not shared with other condensing devices 124.

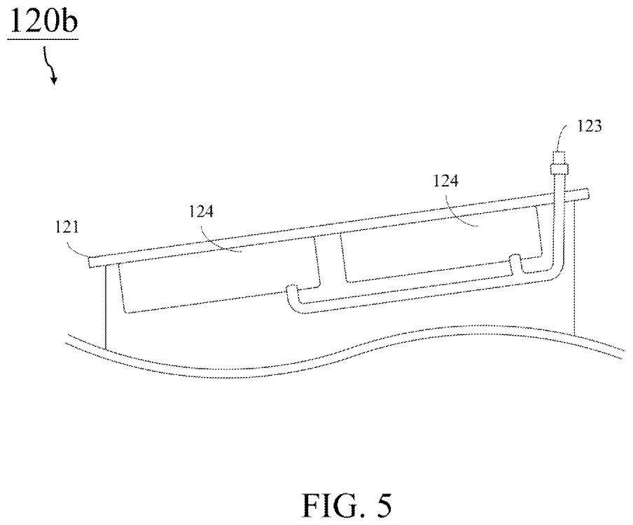

Refer to FIG. 5, which illustrates another side view schematic diagram of the door panel type condensing device according to an embodiment of the application. In this embodiment, the condensing device 124 may be connected to the inlet 122 and the reflux port 123 through piping on the inner side of the door panel 121. This arrangement can reduce the number of components on the exterior of the door panel 121, decrease the chance of external component damage due to unforeseen factors (e.g., improper use), and effectively enhance the overall lifespan of the door panel type condensing device 120b.

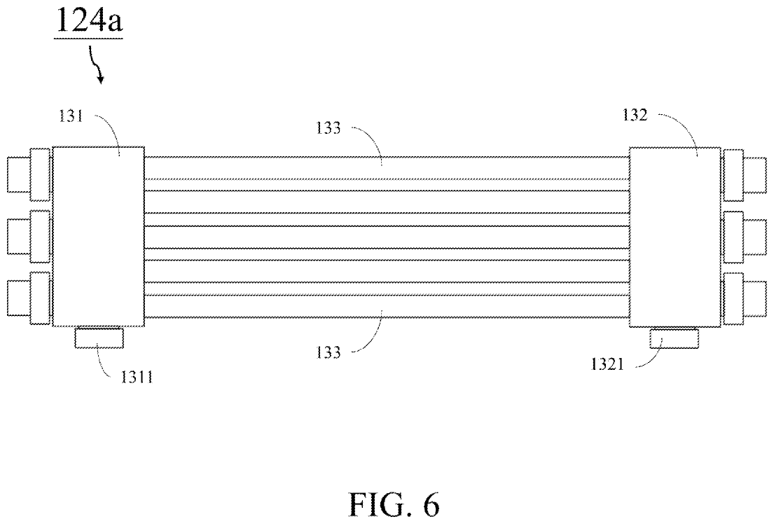

Refer to FIGS. 3 and 6 simultaneously, where FIG. 6 is a schematic diagram of at least one condensing device according to an embodiment of the application. In the embodiment shown in FIG. 6, the condensing device 124a may be implemented as a manifold-type condensing device. In this embodiment, the condensing device 124a includes a first condenser 131, a second condenser 132, and at least one condensing pipeline 133. The first condenser 131 has an inlet 1311 connected to the inlet 122 through piping. The second condenser 132 has an outlet 1321 connected to the reflux port 123 through piping. One end of the at least one condensing pipeline 133 is connected to the first condenser 131, and the other end is connected to the second condenser 132. The at least one condensing pipeline 133 is configured to transfer the coolant from the inlet 1311 to the outlet 1321 of the second condenser 132.

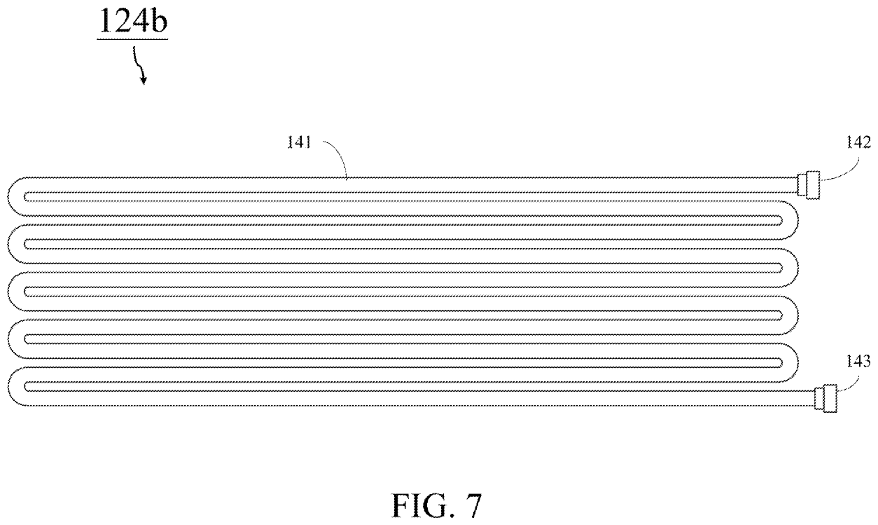

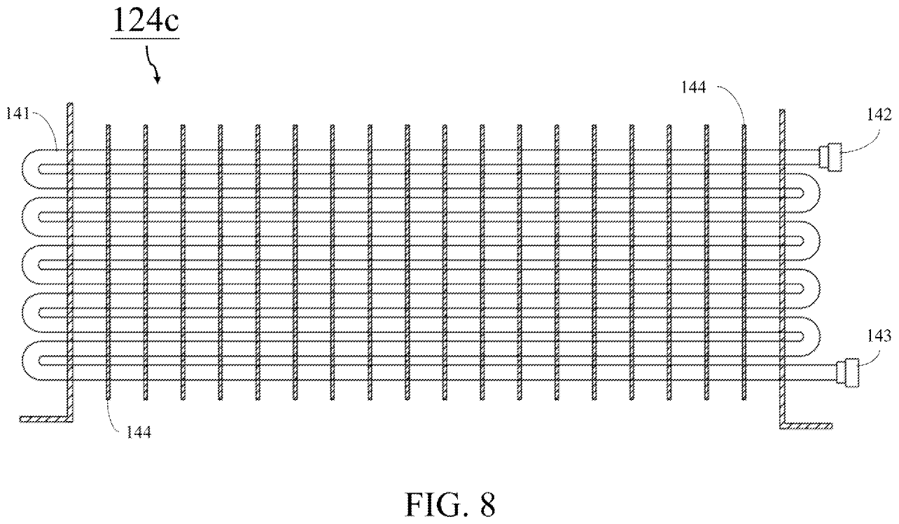

Refer to FIGS. 3 and 7 simultaneously, where FIG. 7 is a schematic diagram of at least one condensing device according to an embodiment of the application. In the embodiment shown in FIG. 7, the condensing device 124b may be implemented as a coil device. In this embodiment, the condensing device 124b includes a coil 141, an inlet 142, and an outlet 143. One end of the coil 141 is connected to the inlet 142, and the other end of the coil 141 is connected to the outlet 143. The inlet 142 is connected to the inlet 122 through piping. The outlet 143 is connected to the reflux port 123 through piping. Refer also to FIG. 8, which differs from the embodiment shown in FIG. 7 in that the condensing device 124b may be implemented as a finned tube cooler. The condensing device 124c further includes multiple fins 144, with the coil 141 passing through these fins 144. Thus, the condensing device 124c can increase the contact area with the electric vapor through multiple fins 144, such that the condensation efficiency of the immersion cooling system is effectively enhanced.

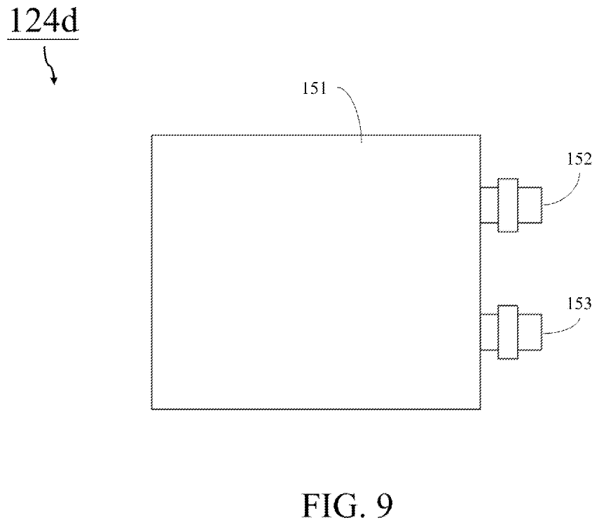

Refer to FIGS. 3 and 9 simultaneously, where FIG. 9 is a schematic diagram of at least one condensing device according to an embodiment of the application. In the embodiment shown in FIG. 9, the condensing device 124d may be implemented as a heat dissipation panel. In this embodiment, the condensing device 124b includes a radiator core 151, an inlet 152, and an outlet 153, wherein the radiator core 151 is connected to both the inlet 152 and the outlet 153. The inlet 152 is connected to the inlet 122 through piping, and the outlet 153 is connected to the reflux port 123 through piping.

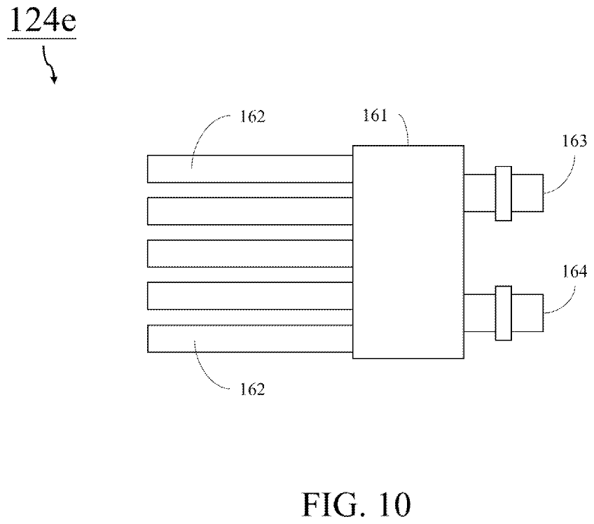

Refer to FIGS. 3 and 10 simultaneously, where FIG. 10 is a schematic diagram of an embodiment of the at least one condensing device. In the embodiment shown in FIG. 10, the condensing device 124e may be implemented as a heat pipe device. In this embodiment, the condensing device 124e includes a condenser 161, at least one condensing tube 162, an inlet 163, and an outlet 164. The condenser 161 is connected to the at least one condensing tube 162, the inlet 163, and the outlet 164. The inlet 163 is connected to the inlet 122 through piping, and the outlet 164 is connected to the reflux port 123 through piping.

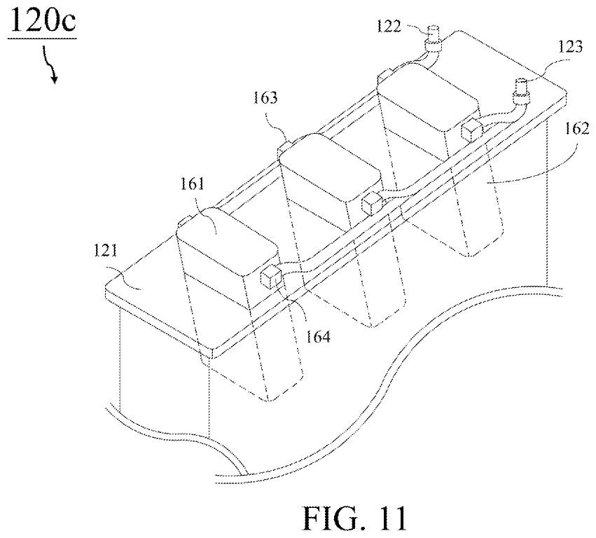

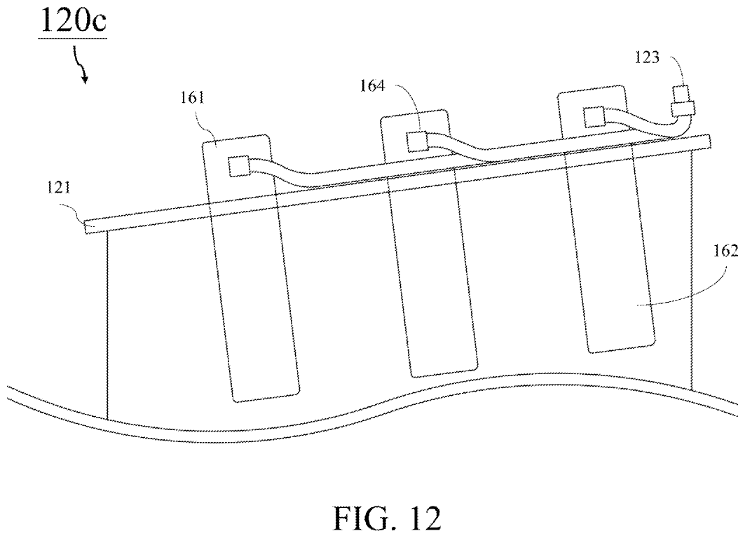

Refer to FIGS. 11 and 12, where FIG. 11 is another schematic diagram of a door panel type condensing device according to an embodiment of the application, and FIG. 12 is a side view of FIG. 11. The difference between the embodiment in FIG. 11 and that in FIG. 3 is that parts of the condensing device 124 in the door panel type condensing device 120c are positioned on the exterior side of the door panel 121. In this embodiment, the condensing device 124 may be realized by the condensing device 124c. The condenser 161, inlet 163, and outlet 164 may be placed on the exterior side of the door panel 121, while the at least one condensing tube 162 may be positioned on the interior side of the door panel 121.

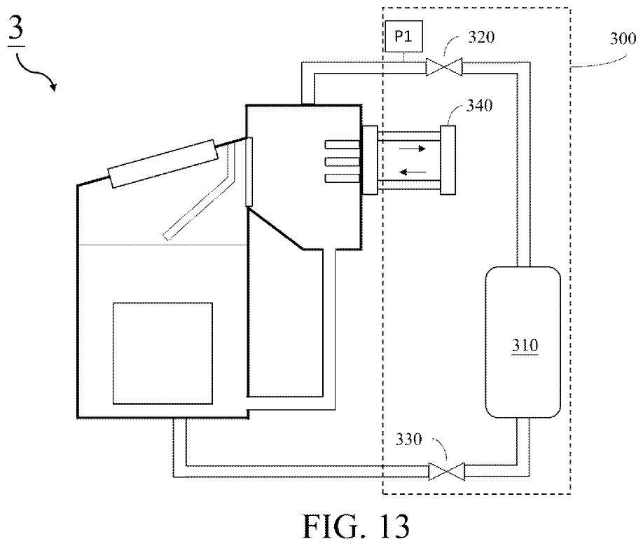

Refer to FIG. 13, which illustrates a schematic diagram of an immersion cooling system according to an embodiment of the application. The immersion cooling system 3 may comprise a coolant distribution device 300 and the tank structure 1 or 2 as described in FIG. 1 or FIG. 2. In this embodiment, the tank structure 2 is merely exemplary, and the actual implementation in the instant application is not limited to this embodiment.

The coolant distribution device 300 includes a liquid-gas storage tank 310, a first valve 320, a second valve 330, a first pressure gauge P1, and a heat exchange device 340. One end of the first valve 320 is connected to the vapor chamber 200 of the tank structure 2 through piping, and the other end of the first valve 320 is connected to the liquid-gas storage tank 310 through piping. The first pressure gauge P1 is installed aside one end of the first valve 320 to measure the air pressure at the end of the first valve 320. The second valve 330 has one end connected to the tank body 110 of the tank structure 2 through piping, whereas the other end of the second valve 330 is connected to the liquid-gas storage tank 310 through piping. The liquid-gas storage tank 310 serves to store spare coolant and electric vapor coming from the vapor chamber 200. The heat exchange device 340 is connected to the condenser 211 of the vapor chamber 200 through piping, arranged to receive hot liquid from the condenser 211 to cool the liquid, and transfer the cooled liquid to the condenser 211 through piping. In one embodiment, the heat exchange device 340 may be, for example, a device with cooling fins, and the actual implementation is not limited to this embodiment.

When the air pressure detected by the first pressure gauge P1 exceeds a predetermined value, suggesting that the vapor pressure within the tank body 100 of the tank structure 2 is too high, the accumulated electric vapor has to be released. Consequently, the first valve 320 is opened to connect the liquid-gas storage tank 310 with the vapor chamber 200, allowing the electric vapor in the vapor chamber 200 to be discharged into the liquid-gas storage tank 310. The electric vapor in the liquid-gas storage tank 310 may spontaneously condense into the coolant 600 as the temperature drops, and the coolant 600 is then stored in the liquid-gas storage tank 310. Therefore, when there is a coolant 600 shortage within the tank body 100, the second valve 330 may be opened to connect the liquid-gas storage tank 310 with the bottom of the tank body 110 of the tank structure 2, allowing the coolant 600 stored in the liquid-gas storage tank 310 to be replenished into the tank body 110.

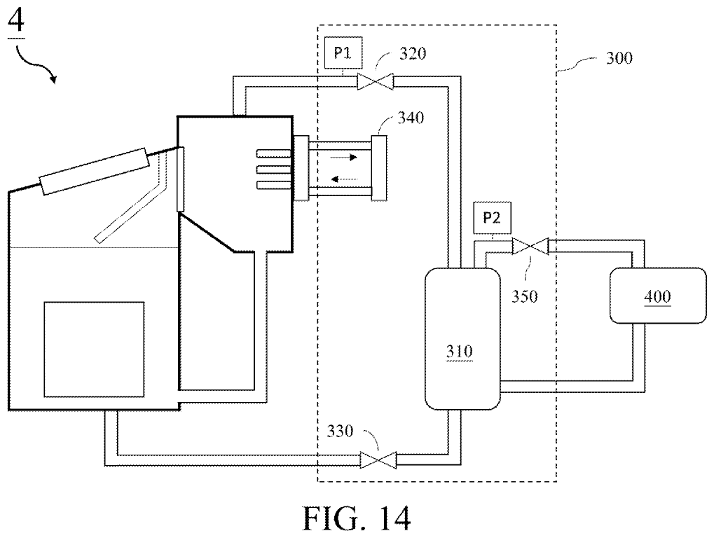

Refer to FIG. 14, which illustrates a schematic diagram of an immersion cooling system according to another embodiment of the application. The difference between FIG. 6 and FIG. 5 is that the immersion cooling system 4 further includes a coolant recovery device 400, and the coolant distribution device 300 further comprises a third valve 350 and a second pressure gauge P2. The third valve 350 has one end connected to the liquid-gas storage tank 310 through piping, and the other end is connected to the coolant recovery device 400 through piping. The coolant recovery device 400 is connected to the bottom of the liquid-gas storage tank 310 through piping. In this embodiment, the coolant recovery device 400 may be selectively connected to the liquid-gas storage tank 310. For example, when the second pressure gauge P2 detects air pressure greater than another predetermined value, indicating that the vapor pressure in the liquid-gas storage tank 310 has become too high, there is a need to release accumulated non-condensable gases that cannot naturally condense. The coolant recovery device 400 then connects to the liquid-gas storage tank 310 through piping, and the third valve 350 will open to allow the non-condensable gases inside the liquid-gas storage tank 310 to be discharged to the coolant recovery device 400. Through this process, non-condensable gases may be processed by the coolant recovery device 400 and converted back into the coolant 600, which is then transferred and stored in the liquid-gas storage tank 310 through piping. Such design prevents the coolant 600 from directly releasing into the atmosphere, avoiding air pollution and loss of the coolant 600, thereby reducing the need for coolant replenishment, and achieving system maintenance cost reductions.

In summary, the tank structure in the embodiments of the application includes a baffle that divides the vapor space into a first and a second vapor space, electric vapor are allowed to be rapidly directed through the baffle to the corresponding first and second vapor spaces. The electric vapor is then cooled by both the door panel type condensing device and the vapor chamber, thereby the condensation efficiency of the electric vapor is significantly enhanced. Moreover, as the tank structure features a door panel type condensing device, the electric vapor circulating to the top plane of the tank structure may be cooled and converted back into liquid, such that the electric vapor is prevented from escaping the cooling system through the door panel structure, and the gas escape rate is effectively reduced. Overall, the immersion cooling system and its tank structure in the embodiments of the application achieve improved cooling efficiency and reduced system maintenance costs. Furthermore, the tank structure has a chamber sealing device, which can selectively enable airflow connection between the second vapor space and the vapor chamber. Therefore, in scenarios where the vapor chamber is connected to multiple tanks, the chamber sealing device can be closed to prevent the electric vapor from escaping during maintenance of any tank, thereby effectively reducing the overall gas escape rate.

The above embodiments illustrate only the principles of the present invention and its efficacy, and are not intended to limit the present invention. Any person familiar with this technique may modify or change the above embodiments without violating the spirit and scope of the present invention. Accordingly, all equivalent modifications or alterations made by those who have ordinary knowledge in the technical field without departing from the spirit and technical ideas revealed in the present invention shall still be covered by the claims of the present invention.

1. A tank structure for an immersion cooling system, comprising:
at least one tank, wherein the at least one tank comprising:
a tank body, having a liquid space and a vapor space, wherein the liquid space is arranged to house a heater device and a coolant, the vapor space is arranged to accommodate electric vapor generated from the coolant, and the vapor space is positioned above the liquid space and adjacent to a top plane of the tank body;
a door panel type condensing device, arranged at the top plane of the tank body, adaptable for sealing the tank body and cooling the electric vapor flowing through the top plane of the tank body; and
a baffle, comprising one end positioned at the top plane of the tank body, and another end directed towards liquid surfaces of the coolant, segmenting the vapor space into a first vapor space near the door panel type condensing device and a second vapor space distal to the door panel type condensing device; and
a vapor chamber, connected to the tank body, adaptable for cooling the electric vapor flowing to the vapor chamber through the second vapor space.

2. The tank structure according to claim 1, wherein the at least one tank comprises a chamber sealing device located between the tank body and the vapor chamber, connected to the tank body, adaptable for selectively allowing partial airflow connectivity between the tank body and the vapor chamber.

3. The tank structure according to claim 2, wherein the chamber sealing device is a movable structure.

4. The tank structure according to claim 1, wherein the vapor chamber comprises a reflux pipeline connected to the tank body, allowing the coolant in the vapor chamber to flow back to the tank body after cooling.

5. The tank structure according to claim 1, wherein the door panel type condensing device comprises:
a door panel, arranged at the top plane of the tank body;
an inlet, arranged on an outer side of the door panel;
a reflux port, arranged on the outer side of the door panel; and
a condensing device, arranged on an inner side of the door panel, and connected to the inlet and the reflux port.

6. The tank structure according to claim 5, wherein the condensing device comprises:
a condenser, arranged on the outer side of the door panel, and connected to the inlet and the reflux port; and
at least one condensing tube, passing through the door panel, and connected to the condenser.

7. The tank structure according to claim 5, wherein the condensing device comprises:
a condenser, passing through the door panel, and connected to the inlet and the reflux port; and
at least one condensing tube, located on the inner side of the door panel, and connected to the condenser.

8. The tank structure according to claim 5, wherein the condensing device comprises:
a first condenser, connected to the inlet;
a second condenser, connected to the reflux port; and
at least one condensing pipeline, connected to the first condenser and the second condenser, and positioned between the first condenser and the second condenser.

9. The tank structure according to claim 5, wherein the condensing device comprises a coil type cooler.

10. The tank structure according to claim 5, wherein the condensing device comprises a finned tube cooler.

11. The tank structure according to claim 1, wherein the baffle comprises a non-heat conducting baffle.

12. The tank structure according to claim 1, wherein the top plane of the tank body is arranged to be inclined with respect to the tank body.

13. An immersion cooling system, comprising:
at least one tank comprising the tank structure of claim 1; and
a coolant distribution device, comprising:
a liquid-gas storage tank, connected to the at least one tank through piping, adaptable for receiving electric vapor from the vapor chamber, and transmitting the coolant to the tank structure of the at least one tank after the coolant is condensed.

14. The immersion cooling system according to claim 13, further comprising:
a coolant recovery device, selectively connected to the liquid-gas storage tank through piping, adaptable for receiving non-condensed gases from the liquid-gas storage tank, and transmitting the coolant to the liquid-gas storage tank after the coolant is condensed.
